(19) United States
(12) Patent Application Publication
(10) Pub. No.: US 2015/0108500 A1
(43) Pub. Date: Apr. 23, 2015

(54) Semiconductor Device and Method of Manufacturing the Same

(71) Applicant: Infineon Technologies Austria AG, Villach (AT)

(72) Inventors: Peter Irsigler, Obernberg am Inn (AT); Hans-Joachim Schulze, Taufkirchen (DE)

(21) Appl. No.: 14/057,532

(22) Filed: Oct. 18, 2013

(51) Int. Cl. H01L 29/778; H01L 29/66; H01L 29/10; H01L 29/16

(52) U.S. Cl. CPC H01L 29/7787; H01L 29/1608; H01L 29/66431; H01L 29/1095
USPC 257/77; 438/172

(57) ABSTRACT

A semiconductor device comprises a semiconductor body of a first semiconductor material, wherein at least a part of the semiconductor body constitutes a drift zone of a first conductivity type. The semiconductor device further comprises a channel layer structure comprising a semiconductor heterojunction between first and second semiconductor layers electrically coupled to the drift zone. The first and second semiconductor layers include semiconductor materials that are different to the first semiconductor material.

### BACKGROUND

A key component in semiconductor applications is a solid-state switch. As an example, switches turn loads of automotive applications or industrial applications on and off. Solid-state switches typically include, for example, field effect transistors (FETs) like metal-oxide-semiconductor FETs (MOSFETs) or insulated gate bipolar transistors (IGBTs).

Key demands on solid-state switches are low on-state resistance and high breakdown voltage Minimization of the on-state resistance typically leads to an increase in breakdown voltage. Therefore, a trade-off between the on-state resistance and the breakdown voltage has to be met. Accordingly, it is desirable to provide a semiconductor device having an optimized on-state resistance and breakdown voltage.

### SUMMARY

According to an embodiment of a semiconductor device, the semiconductor device comprises a semiconductor body of a first semiconductor material. At least a part of the semiconductor body constitutes a drift zone of a first conductivity type. The semiconductor device further comprises a channel layer structure comprising a semiconductor heterojunction between first and second semiconductor layers electrically coupled to the drift zone. The first and second semiconductor layers include semiconductor materials that are different to the first semiconductor material.

According to another embodiment of a semiconductor device, the semiconductor device comprises a semiconductor body of SiC. At least a part of the semiconductor body of SiC constitutes a drift zone. The semiconductor device further comprises a channel layer structure comprising a high electron mobility transistor structure that is electrically connected to the drift zone. In addition, the semiconductor device comprises a charge compensation structure in the semiconductor body of SiC.

According to an embodiment of a method of manufacturing a semiconductor device, the method comprises etching at least one trench in a semiconductor body of SiC. The method further includes doping a part of the semiconductor body of SiC via sidewalls of the at least one trench. In addition, the method comprises forming a high electron mobility transistor structure in a channel layer structure above the semiconductor body of SiC.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the present invention and are incorporated in and constitute a part of the specification. The drawings illustrate embodiments of the present invention and together with the description serve to explain principles of the invention. Other embodiments of the invention and many of the intended advantages will be readily appreciated as they become better understood by reference to the following detailed description. The elements of the drawings are not necessarily to scale relative to each other. Like reference numerals designate corresponding similar parts.

FIG. 1A is a schematic cross-sectional view of a portion of a semiconductor device according to an embodiment.

FIG. 1B is a detailed view of a channel layer structure of the semiconductor device of FIG. 1 in accordance with an embodiment.

FIG. 1C is a detailed view of a charge compensation structure of the semiconductor device of FIG. 1 in accordance with an embodiment.

FIG. 1D is a schematic cross-sectional view of a portion of a semiconductor device according to another embodiment.

FIG. 2 is a schematic process chart of one embodiment of a method of manufacturing a semiconductor device according to an embodiment.

FIG. 3 is a schematic cross-sectional view illustrating formation of a semiconductor layer on a semiconductor substrate in accordance with an embodiment.

FIG. 4 is a cross-sectional view illustrating an etching process of at least one trench in a semiconductor body in accordance with an embodiment.

FIG. 5A is a cross-sectional view illustrating a doping process of a part of the semiconductor body via sidewalls of the at least one trench by an angle implantation process in accordance with an embodiment.

FIG. 5B is a cross-sectional view illustrating a doping process of a part of the semiconductor body via sidewalls of the at least one trench by plasma doping in accordance with an embodiment.

FIG. 6 is a cross-sectional view illustrating a filling process of the at least one trench with a filling material in accordance with an embodiment.

FIGS. 7 to 9 are cross-sectional views illustrating forming a source contact zone and a drift contact zone in the semiconductor body and forming a high electron mobility transistor structure in a channel layer structure above the semiconductor body in accordance with an embodiment.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” “over,” “above,” “below,” etc., is used with reference to the orientation of the Figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements or manufacturing processes have been designated by the same references in the different drawings if not stated otherwise.

The terms “lateral” and “horizontal” as used in this specification intends to describe an orientation parallel to a first surface of a semiconductor substrate or semiconductor body. This can be for instance the surface of a wafer or a die.

The term “vertical” as used in this specification intends to describe an orientation which is arranged perpendicular to the first surface of the semiconductor substrate or semiconductor body.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

In this specification, n-doped may refer to a first conductivity type while p-doped is referred to a second conductivity type. Nonetheless, the semiconductor devices can be formed with opposite doping relations so that the first conductivity type can be p-doped and the second conductivity type can be n-doped. Furthermore, some Figures illustrate relative doping concentrations by indicating “⁻” or “⁺” next to the doping type. For example, “n⁻” means a doping concentration which is less than the doping concentration of an “n”-doping region while an “n⁺”-doping region has a larger doping concentration than the “n⁻”-doping region. Indicating the relative doping concentration does not, however, mean that doping regions of the same relative doping concentration have the same absolute doping concentration unless otherwise stated. For example, two different n⁺ regions can have different absolute doping concentrations. The same applies, for example, to an n⁺ and a p⁺ region.

Specific embodiments described in this specification pertain to, without being limited thereto, power semiconductor devices which are controlled by field-effect and particularly to unipolar devices such as MOSFETs.

The term “field-effect” as used in this specification intends to describe the electric field mediated formation of an “inversion channel” and/or control of conductivity and/or shape of the inversion channel in a semiconductor channel region.

In the context of the present specification, the term “MOS” (metal-oxide-semiconductor) should be understood as including the more general term “MIS” (metal-insulator-semiconductor). For example, the term MOSFET (metal-oxide-semiconductor field-effect transistor) should be understood to include FETs having a gate insulator that is not an oxide, i.e., the term MOSFET is used in the more general term meaning IGFET (insulated-gate field-effect transistor) and MISFET, respectively.

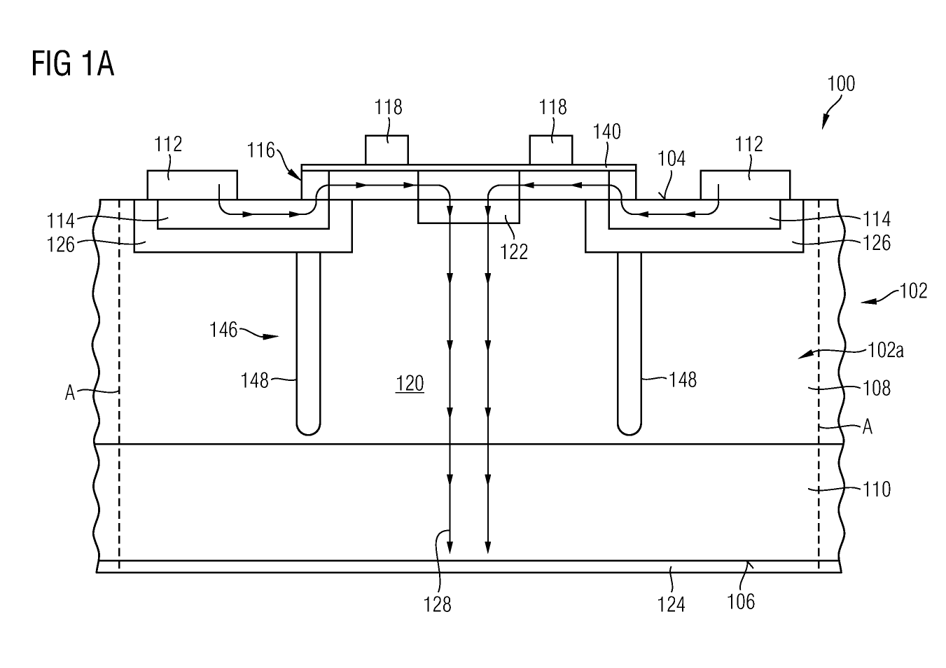

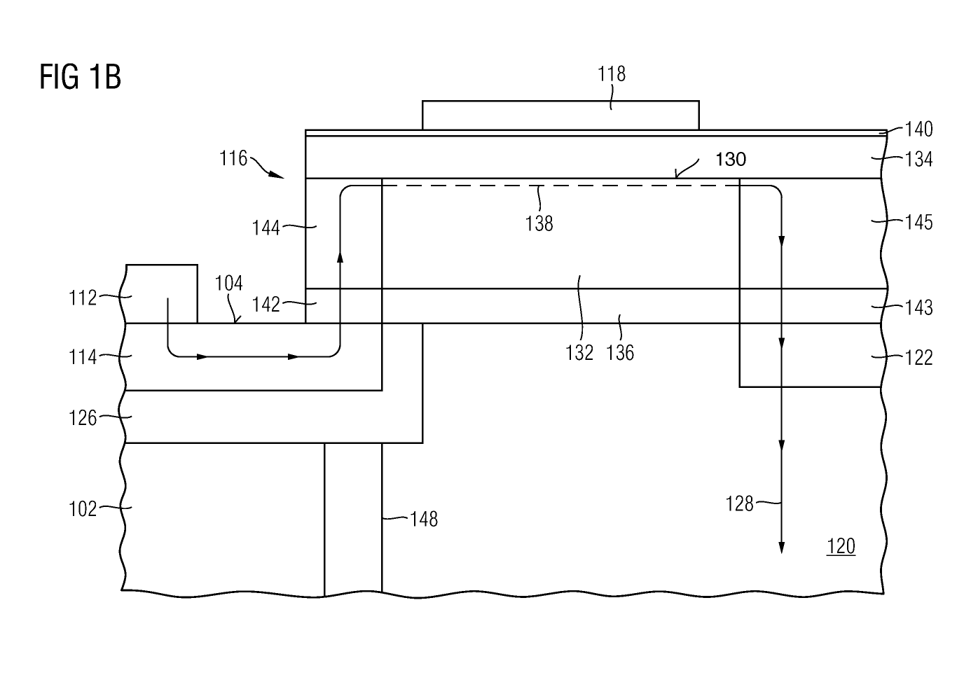

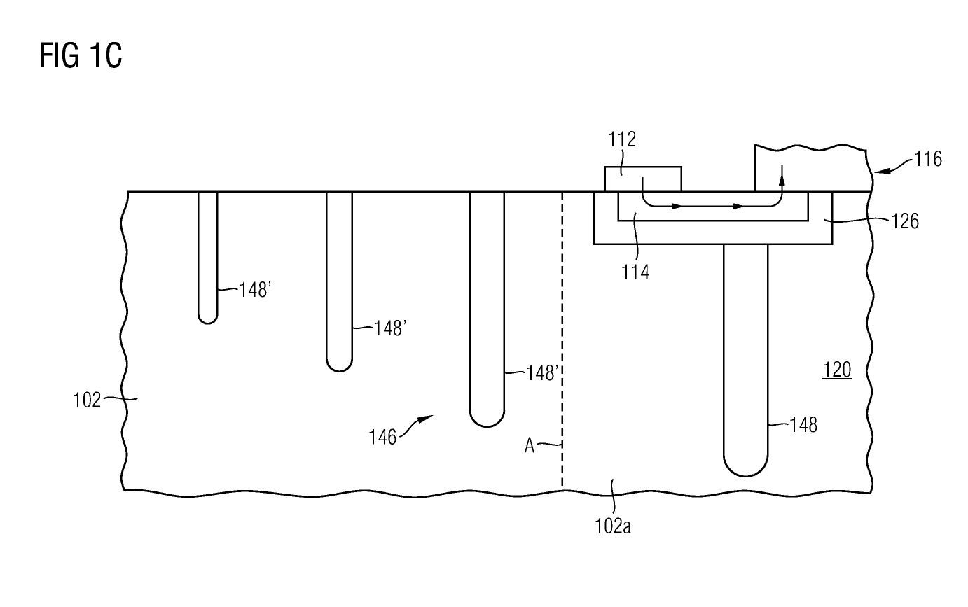

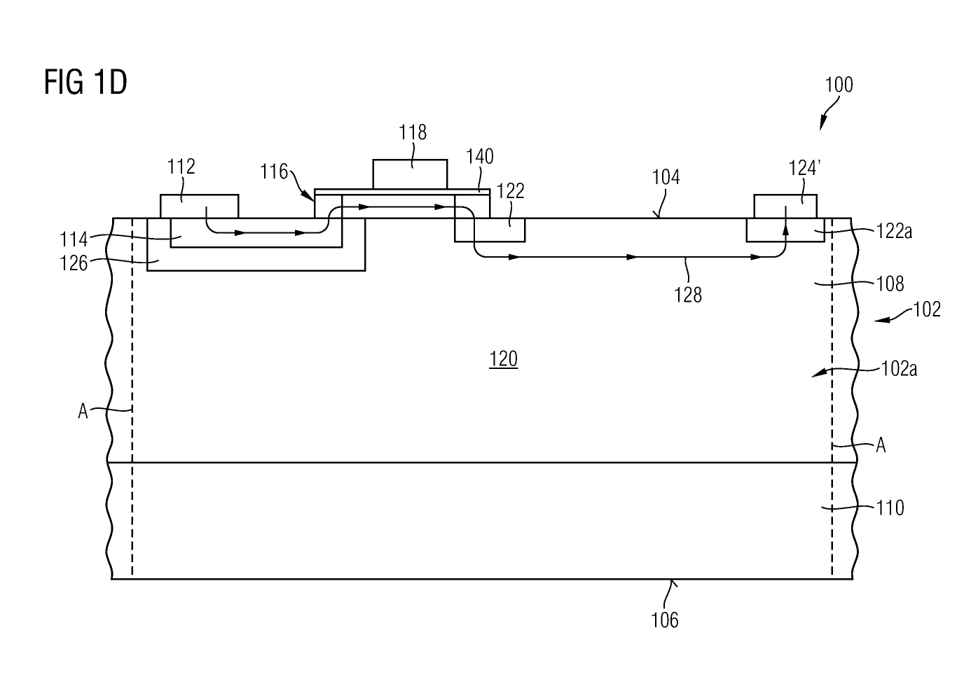

FIG. 1A shows a schematic cross-sectional view of a portion of a semiconductor device 100, according to an embodiment. The semiconductor device 100 includes a semiconductor body 102 having a first surface 104 and a second surface 106 that is opposite to the first surface 104. The semiconductor body 102 includes a first semiconductor material, for example silicon Si, germanium Ge, silicon germanium SiGe, gallium nitride GaN or gallium arsenide GaAs. In an embodiment, the first semiconductor material includes SiC. The semiconductor body 102 may include a semiconductor layer structure 108 having one or more semiconductor layer(s), e.g. epitaxial layer(s), on a semiconductor substrate 110. Outside the illustrated portion, the semiconductor body 102 may include, inter alia, further doped and undoped sections, semiconductor layers, insulating and conducting structures, for example.

Within a transistor cell area 102a of the semiconductor body 102, as indicated by dashed lines A in FIG. 1A, the semiconductor device 100 includes source electrodes 112 on the first surface 104 of the semiconductor body 102 being electrically coupled to source contact zones 114 of a first conductivity type in the semiconductor body 102. The source contact zones 114 directly adjoin the first surface 104 and extend from the first surface 104 into the semiconductor body 102. The source contact zones 114 are electrically coupled to a channel layer structure 116 on the first surface 104. On the channel layer structure 116, a gate dielectric layer 140 and a gate electrode 118 are formed in this order. The gate dielectric layer may comprise a dielectric material like an oxide or a nitride. The gate electrode 118 is configured to control a conductivity of the channel layer structure 116 via a voltage applied to the gate electrode 118. The channel layer structure 116 is electrically coupled to a drift zone 120 in at least a part of the semiconductor body 102 via a drift contact zone 122. The drift contact zone 122 of the first conductivity type adjoins the first surface 104 of the semiconductor body 102 and is electrically coupled to the channel layer structure 116. The drift contact zone 122 further extends into the semiconductor body 102 for contacting the drift zone 120 in the semiconductor body 102. The drift contact zone 122 and the drift zone 120 are of a first conductivity type. At the second surface 106 of the semiconductor body 102, a drain electrode 124 is provided. The drain electrode 124 at the second surface 106 of the semiconductor body 102 is electrically coupled to the drift zone 120. Junction isolation zones 126 of a second conductivity type are provided in the semiconductor body 102 for electrically insulating the source contact zones 114 from the drift zone 120 and to enable the desired blocking capability of the device. A current path 128 between the source electrodes 112 at the first surface 104 and the drain electrode 124 at the second surface 106 is denoted by a line and includes the channel layer structure 116 on the semiconductor body 102 and the drift zone 120 within the semiconductor body 102.

In FIG. 1B, a detailed view of the channel layer structure 116 is shown. The channel layer structure 116 on the first surface 104 comprises a heterojunction 130 between first and second semiconductor layers 132, 134 being electrically coupled to the drift zone 120. The first semiconductor layer 132 and the second semiconductor layer 134 include semiconductor materials being different to the first semiconductor material of the semiconductor body 102. The channel layer structure 116 may comprise an optional buffer layer 136 between the heterojunction 130 and the semiconductor body 102 for minimizing strain. In an embodiment, the channel layer structure 116 includes a high electron mobility transistor structure, which comprises the heterojunction 130 between the first semiconductor layer 132 and the second semiconductor layer 134 consisting of at least two different semiconductor materials brought into intimate contact. Because of the different bandgaps and their relative alignment to each other, band discontinuities occur at the interface between the two different semiconductor materials. By choosing proper materials and compositions thereof, the conduction band offset can form a triangular shape potential well confining electrons in a horizontal direction being parallel to the first surface 104. Within the well the electrons flow in a two-dimensional plane parallel to the heterojunction 130 and are therefore referred to as a two-dimensional electron gas. The two-dimensional electron gas 138 is denoted by a dashed line.

In an embodiment, the channel layer structure 116 may include Si, Ge, multilayer graphene, molybdenum disulfide, or further material compositions being configured to generate a two-dimensional electron gas 138 within the channel layer structure 116. In some of these embodiments, it can be sufficient to implement only one layer instead of the first and second semiconductor layers 132, 134 on the surface of the semiconductor body 102 comprising the drift zone 120 or on the buffer layer 136. The resulting high electron mobility transistor structure may thus be formed by either a semiconductor heterojunction or a single layer structure providing a two-dimensional electron gas 138.

In an embodiment, the channel layer structure 116 includes a GaN/AlGaN semiconductor material composition formed on the semiconductor body 102. The semiconductor body 102 may include SiC. The first semiconductor layer 132 may include GaN and the second semiconductor layer 134 may include AlGaN. The second semiconductor layer 134 of AlGaN acts as a barrier layer for the first semiconductor layer 132 and forms a heterojunction between the first and second semiconductor layers 132, 134. In an embodiment, the gate dielectric layer 140 includes an oxide like Al₂O₃ on the second semiconductor layer 134 of Al—GaN. The first semiconductor layer 132 may be an undoped layer. The second semiconductor layer 134 may be of the first conductivity type.

According to the embodiment of a GaN/AlGaN-heterojunction 130, no separate doping of the second semiconductor layer 134 of AlGaN is required, since the two-dimensional electron gas 138 is induced by built-in polarization fields due to a spontaneous polarization and piezo-polarization between the first semiconductor layer 132 of GaN and the second semiconductor layer 134 of AlGaN. Due to the large conduction band discontinuity of the GaN/AlGaN-heterojunction 130, a high charge carrier concentration of the two-dimensional electron gas 138 can be achieved, which may be above 10¹³ cm². The wide bandgap of GaN allows the semiconductor device 100 to withstand high operating temperatures in the range of 300° C. to 500° C. enabling applications in many commercial areas not covered by other semiconductor materials. In addition, the wide bandgaps of 3.4 eV/3.3 eV of the GaN/AlGaN semiconductor material system result in high electric breakdown fields, which enable applications at high supply voltages.

The buffer layer 136 may be of GaN and is provided to reduce the strain caused by lattice mismatch between the first semiconductor layer 132 and the semiconductor body. The buffer layer 136 may be an undoped layer. In order to electrically connect the source contact zone 114 and the drift contact zone 122 to the two-dimensional electron gas 138 in the first semiconductor layer 132 next to the heterojunction 130 between the first semiconductor layer 132 and the second semiconductor layer 134, first and second contact zones 142, 143 in the buffer layer 136 and first and second contact zones 144, 145 in the first semiconductor layer 132 are provided, which may be of a first conductivity type. The first contact zones 142, 144 in the buffer layer 136 and in the first semiconductor layer 132 are formed on the source contact zone 114, whereas the second contact zones 143, 145 in the buffer layer 136 and in the first semiconductor layer 132 are formed on the drift contact zone 122. An electrical contact between a source, e.g. the source contact zone 114, and the two-dimensional electron gas 138 and/or between the two-dimensional electron gas 138 and the drift zone 120 may also be formed by a low resistive layer structure of metal and/or carbon.

The two-dimensional electron gas 138 in the first semiconductor layer 132 is induced or not induced, depending on a voltage applied to the gate electrode 118. Thus, the current path 128 from the source electrode 112 to the drift contact zone 122 can be switched by the existence or non-existence of the two-dimensional electron gas 138 in the first semiconductor layer 132. By introducing fixed charge carriers in the gate dielectric layer 140, a normally-off transistor device can be formed.

By combining a channel layer structure 116 including the high electron mobility transistor structure as described above and a drift zone 120 in the semiconductor body 102, a low on-state resistance can be achieved due to the two-dimensional electron gas 138, whereas at the same time a high breakdown voltage is achieved by the drift zone 120 in the semiconductor body 102.

As further shown in FIG. 1A, a charge compensation structure 146 may be provided in the semiconductor body 102. The charge compensation structure 146 includes at least one charge compensation region of a conductivity type that is complementary to the conductivity type of the drift zone 120 and forms a superjunction structure within the semiconductor body 102 between the drift contact zone 122 and the drain electrode 124. In an embodiment, the charge compensation structure 146 comprises at least one trench 148 extending into the semiconductor body 102 towards the second surface 106. In an embodiment, the width of the trench(es) 148 is smaller than 1 μm or smaller than 0.5 μm. The trench(es) 148 may be filled with a doped semiconductor material being the same semiconductor material as the material used for the semiconductor body 102 for the case that a doping of the side wall with the complementary doping type took place before or alternatively with material of the other doping type serving as complementary doping type. In an embodiment, the trench(es) 148 may be filled with doped SiC, in case the semiconductor body 102 includes SiC. Alternatively, the trench(es) 148 may be filled with an insulating material like diamond, boron nitride or phase change materials, to increase the heat conductance or heat capacity of the semiconductor device 100. The ratio of the width of the drift zone 120 and a trench(es) 148 of the charge compensation structure 146 may be higher than 5, higher than 10, or higher than 100.

As shown in a detailed view of FIG. 1C, the semiconductor device 100 may, in a further embodiment, comprise an edge termination structure having trenches 148′, which decrease in depth with increasing distance from the transistor cell area 102a of the semiconductor body 102. The variation in depth of the trenches 148′ can be achieved by decreasing the width of the respective trenches 148′ leading to a decreased depth due to a lower etching rate in a reactive ion etching process, thus the trenches 148 and 148′ can be simultaneously formed in a single etching step. This results in an effective edge termination for the transistor cell area 102a.

Hence, a semiconductor device 100 is provided, which comprises a semiconductor body 102 of SiC having a first surface 104 and a second surface 106 opposite to the first surface 104, wherein at least a part of the semiconductor body 102 of SiC constitutes the drift zone 120. The channel layer structure 116 is provided on the first surface 104 and comprises a high electron mobility transistor structure being electrically connected to the drift zone 120. Furthermore, optionally a charge compensation structure 146 is provided in the semiconductor body 102 of SiC.

FIG. 1D illustrates a schematic cross-sectional view of a portion of a semiconductor device 100 according to another embodiment. The semiconductor device 100 as shown in FIG. 1D differs from the semiconductor device 100 as shown in FIG. 1A in that the drift zone 120 is provided in a lateral direction within the semiconductor body 102, wherein a drain electrode 124′ is formed on the first surface 104 of the semiconductor body 102. An additional drift contact zone 122a of the first conductivity type adjoins the first surface 104 of the semiconductor body 102 and is electrically coupled to the drain electrode 124′. The additional drift contact zone 122a further extends into the semiconductor body 102 for contacting the drift zone 120 in the semiconductor body 102. The additional drift contact zone 122a is of a first conductivity type.

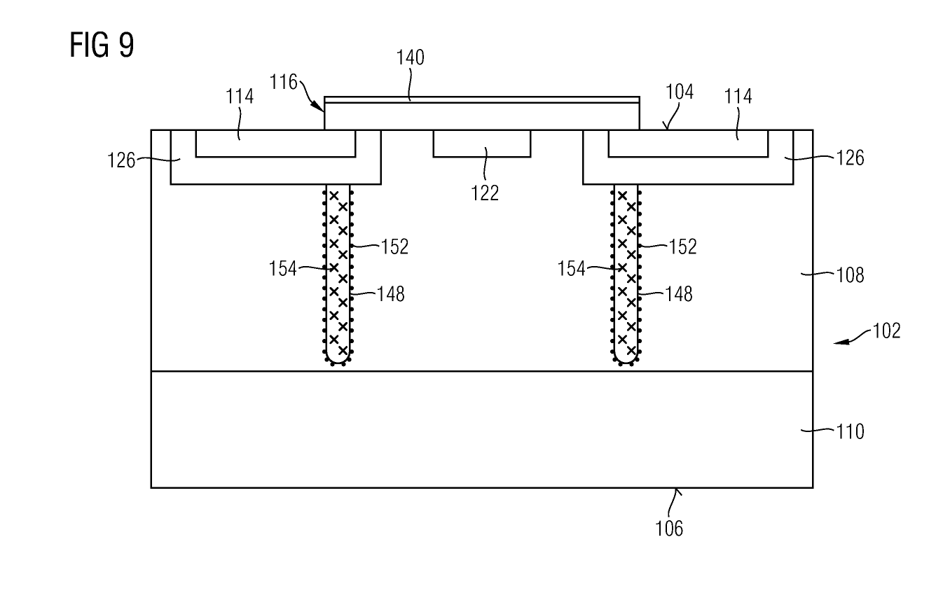

The channel layer structure 116 as shown in FIGS. 1A to 1D and 9 is formed on the first surface 104 of the semiconductor body 102, thus the two-dimensional electron gas 138 extends in a lateral direction with respect to the first surface 104. In another embodiment, the channel layer structure 116 may be formed on a side wall of a trench (not shown) extending into the semiconductor body 102 towards the second surface 106, thus the two-dimensional electron gas 138 may extend in a vertical direction with respect to the first surface 104 or parallel to the side wall of the trench. A respective drift zone 120 within the semiconductor body 102 may then extend either in a lateral direction or a vertical direction in accordance with the embodiments as shown in FIG. 1A or 1D.

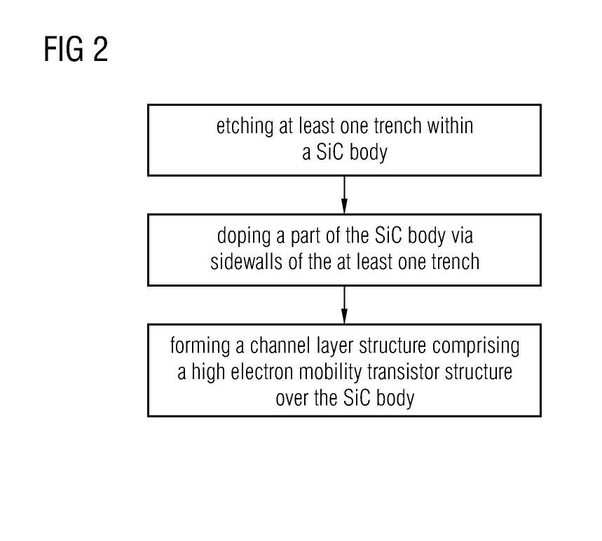

FIG. 2 illustrates a schematic process chart of a method of manufacturing a semiconductor device. Process feature S100 includes etching at least one trench within a semiconductor body of SiC. Process feature S110 includes doping a part of the semiconductor body of SiC via sidewalls of the at least one trench. Process feature S120 includes forming a channel layer structure comprising a high electron mobility transistor structure over the semiconductor body of SiC.

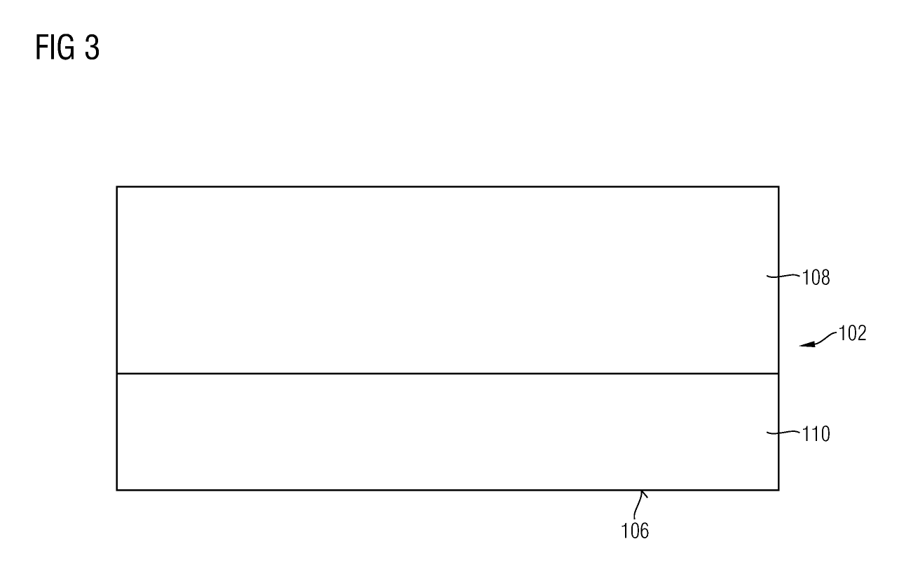

In FIGS. 3 to 9, a method of manufacturing the semiconductor device 100 according to an embodiment will be described with reference to cross-sectional views for illustration of selected processes.

As shown in FIG. 3, a semiconductor layer structure 108 is grown on a semiconductor substrate 110 to provide a semiconductor body 102. The semiconductor layer structure 108 and the semiconductor substrate 110 may include SiC. As an example, a thickness of the semiconductor layer(s) formed on the semiconductor substrate 110 as well as a doping concentration of the one or several layers of the semiconductor layer structure 108 may be appropriately chosen with regard to a desired voltage blocking capability of the semiconductor device 100 that is to be formed in the semiconductor body 102.

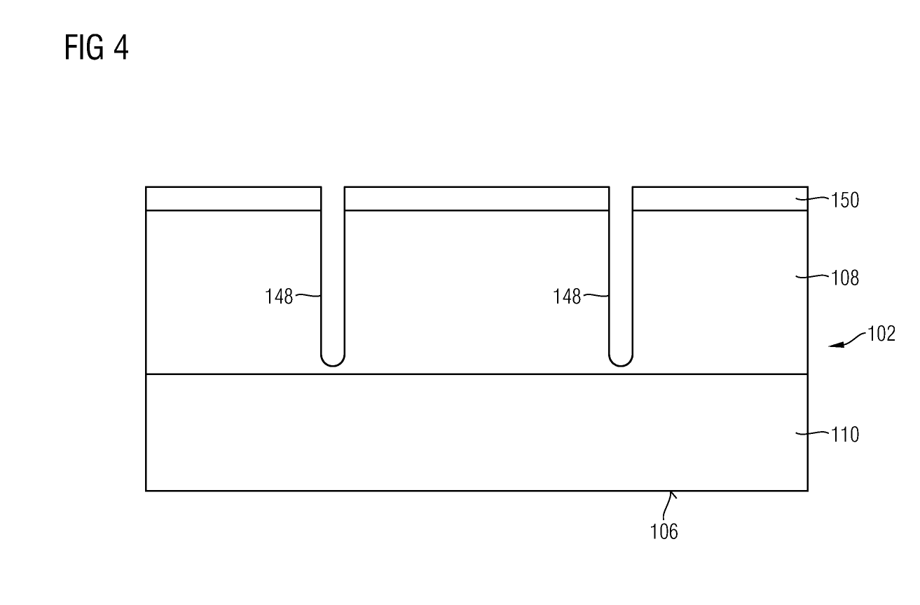

As shown in FIG. 4, at least one trench 148 is etched within the semiconductor body 102 using a patterned mask layer 150. The at least one trench 148 extends into the semiconductor body 102 in the direction of the second surface 106. The at least one trench 148 may be formed by an appropriate process, e.g. dry and/or wet etching. As an example, the at least one trench 148 may be formed in the semiconductor body 102 by an anisotropic plasma etch process, e.g. reactive ion etching (RIE) using an appropriate etch gas, e.g. at least one of Cl₂, Br₂, CCl₄, CHCl₃, CHBr₃, BCl₃, HBr. According to an embodiment, sidewalls of the at least one trench 148 may be slightly tapered, e.g. including a taper angle between 88° and 90°. Slightly tapered trench sidewalls may be beneficial with regard to avoiding trench cavities when filling up trenches.

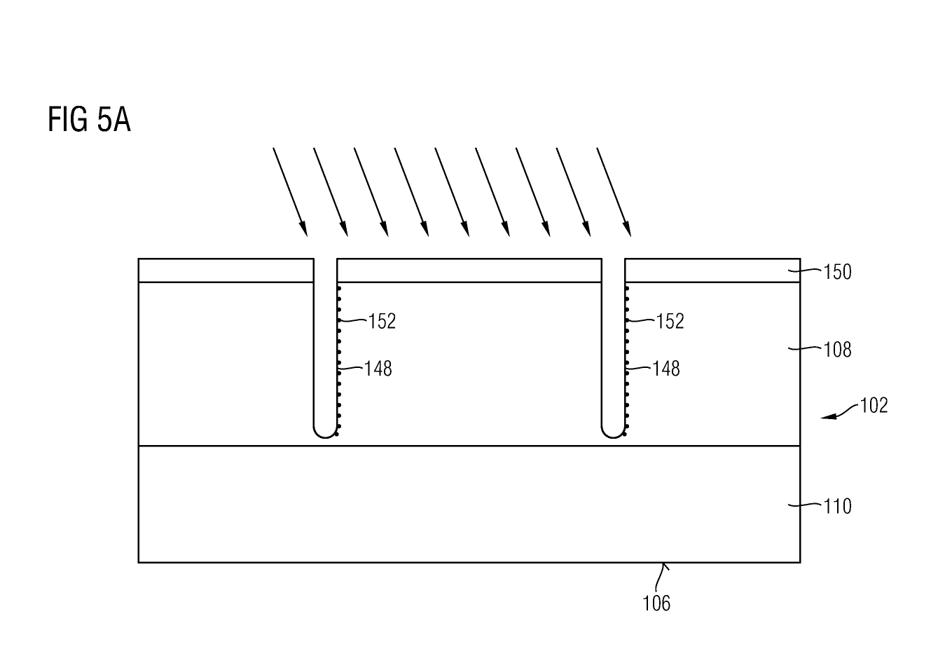

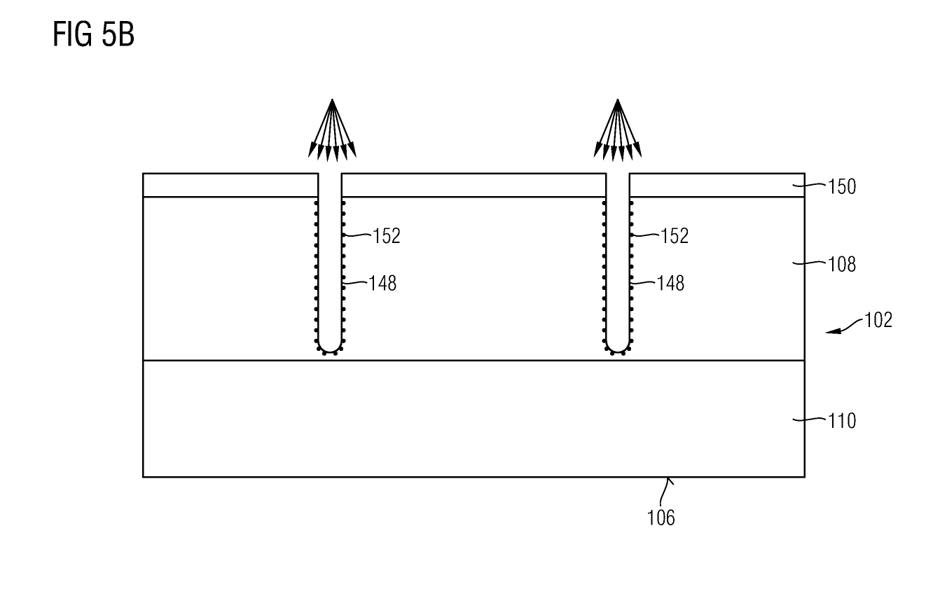

FIGS. 5A and 5B illustrate two embodiments of doping a part of the semiconductor body 102 via sidewalls of the at least one trench 148.

In FIG. 5A, dopants 152 are introduced into a layer of the semiconductor body 102 lining the sidewalls of the trench 148 by a tilted ion implantation process. For doping of the part of the semiconductor body 102 via the sidewalls of the trench 148 down to the bottom part of the trench 148, the implantation angle should be chosen with respect to the aspect ratio of the trench 148. As shown in FIG. 5A, only one lateral side of the sidewalls of the at least one trench 148 is doped, since the opposite side of the sidewalls of the trench 148 is shadowed by the semiconductor body 102. The opposite side of the sidewalls of the trench 148 may also be doped by repeating the above tilted ion implantation process under a different angle.

According to another embodiment of the method for manufacturing the semiconductor device 100 illustrated in FIG. 5B, dopants 152 are introduced uniformly in the semiconductor body 102 via the sidewalls of the at least one trench 148 by a plasma doping process. Plasma doping of the part of the semiconductor body 102 via sidewalls of the at least one trench 148 allows high dose implants at low energies and is also known as PLAD (plasma doping) or PIII (plasma immersion ion implantation). These methods allow for a precise doping of the part of the semiconductor body at the trench sidewalls. A conformal doping of the part of the semiconductor body 102 at the trench sidewalls can be achieved by applying a voltage to a substrate surrounded by a radio frequency (RF) plasma including a dopant gas. Collisions between ions and neutral atoms as well as the biasing of the semiconductor substrate 110 lead to a broad annular distribution of the dopants allowing for a homogeneous doping over the trench sidewalls. Also a small vertical gradient in dose of doping in the part of the semiconductor body 102 may be achieved by plasma doping. This allows for a vertical variation of a degree of charge compensation improving stability of manufacture and/or avalanche robustness. A vertical variation of dose of doping may be smaller 20%, or smaller than 10% or smaller than 5%.

When doping with PLAD, the semiconductor body 102 having the at least one trench 148 is exposed to a plasma including ions of dopants. These ions are accelerated by an electric field towards the semiconductor body 102 and are implanted into an exposed surface of the substrate. An implanted dose can be adjusted or controlled via DC voltage pulses, e.g. negative voltage pulses. A Faraday system allows to adjust or control the dose. Two sets of coils, i.e. a horizontal coil and a vertical coil allow to generate the plasma and keep it homogeneous. An ion density can be adjusted via a distance between the coils and the substrate. Interaction between the vertical coils and the horizontal coils allows to adjust or control homogeneity and the ion density.

A penetration depth of the dopants into the semiconductor body and the implant dose may be adjusted via a pulsed DC voltage applied between the semiconductor body 102 and a shield ring surrounding it.

According to an embodiment, doping the part of the semiconductor body 102 by plasma doping includes introducing the dopants into the part of the semiconductor body 102 via the sidewalls at a dose in a range of 5×10¹¹ cm⁻² to 3×10¹³ cm⁻², or in a range of 1×10¹² cm⁻² to 2×10^{—}cm⁻². This comparatively low dose requires modifications of the pulsed DC voltage typically used. Typically doses exceeding 10¹⁵ cm⁻² are implanted by these techniques. According to an embodiment, a pulse distance of the DC voltage pulses is adjusted in a range of 100 μs to 10 ms, in particular between 500 μs and 5 ms. A DC voltage pulse rise time is set to a value smaller than 0.1 μs, for example. According to an embodiment a pulse width ranges between 0.5 μs to 20 μs, or between 1 μs to 10 μs.

The employment of the plasma doping in combination with a semiconductor body 102 of SiC enables a charge compensation structure 146 having doped regions with a very low width due to the small diffusion constant of the dopants in SiC. Thus, a large region for the drift zone 120 can be maintained in the semiconductor device 100, which further reduces Qoss (charge lost at device output).

The lateral diameter of the at least trench 148 may be in a range below 2 μm or even below 300 nm. Due to the relative high dopant concentration in the charge compensation area, the mobility of the free charge carriers is reduced and thus also a voltage blocking capability of the semiconductor device 100 is increased.

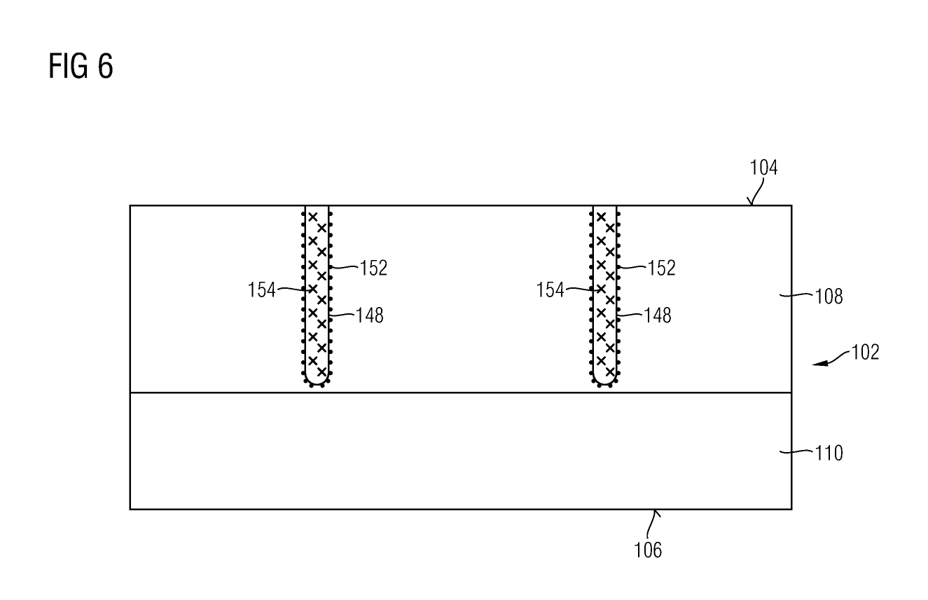

As shown in FIG. 6, the trench 148 is at least partly filled up with a filling material 154 being an insulating material and/or a semiconductor material formed by lateral epitaxial processes or by CVD.

In the case of filling up the trench 148 with a semiconductor material, the semiconductor material may be undoped or may typically include a doping concentration below the doping concentration introduced by the above-described plasma doping of the doped part of trench(es) 148 or may include a doping concentration which is similar to the doping of the semiconductor body 102 so that it can contribute to a current flow with low resistance. The trench(es) 148 may be filled with doped SiC, wherein the dopant concentration of the filling material may be set such that the charge compensation effect is maintained. Since the charge compensation dose in SiC is relatively high due to the wide bandgap of this semiconductor material, the dose of the dopants introduced by plasma deposition into the sidewalls of the trench 148 is comparatively precise and very homogeneous.

In case of filling the trench 148 with an insulating material, the trench 148 may be filled with diamond, boron nitride or phase change materials to enhance the heat conductivity or heat capacity of the semiconductor body 102.

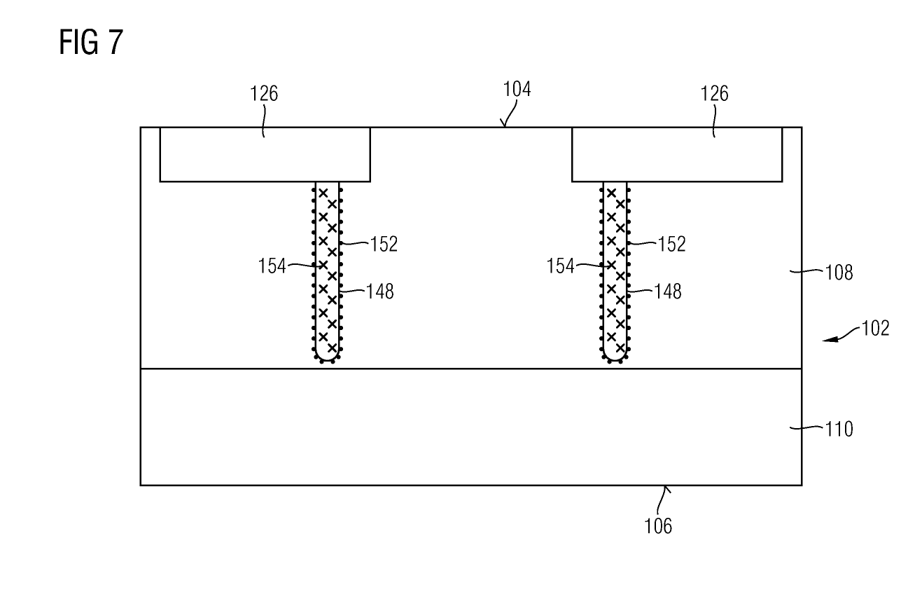

As shown in FIG. 7, junction isolation zones 126 or p-body zones of the second conductivity type are formed in the semiconductor body 102 of the first conductivity type.

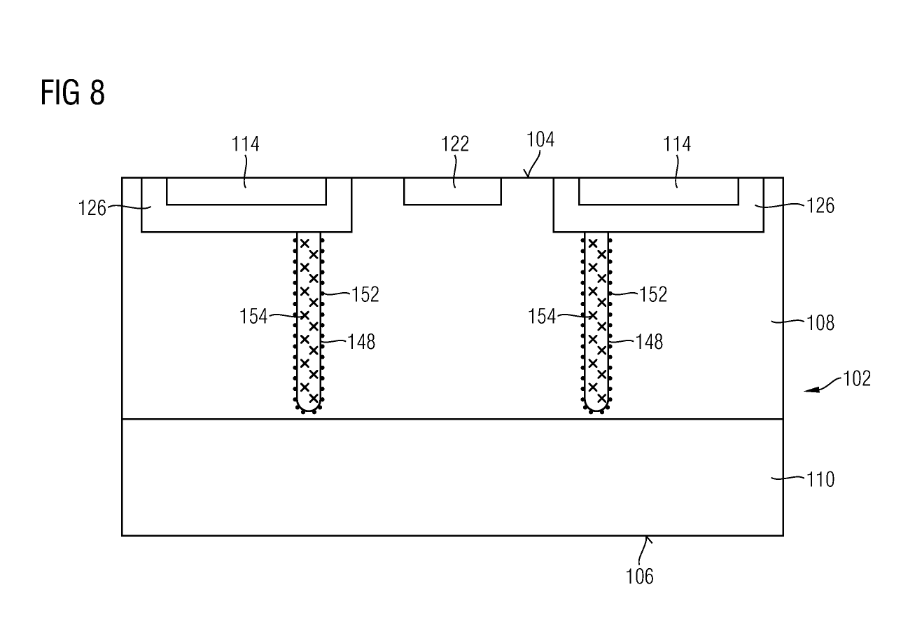

As shown in FIG. 8, source contact zones 114 and a drift contact zone 122 of the first conductivity type are formed in the semiconductor body 102, wherein the source contact zones 114 are insulated from the semiconductor body 102 and the drift zone 120 by the junction isolation zones 126 or body zones of the second conductivity type providing a pn-junction isolation.

As shown in FIG. 9, the channel layer structure 116 as described above is formed together with the gate dielectric layer 140 on the first surface 104 of the semiconductor body 102. Finally, the semiconductor device 100 is provided with source electrodes 112 and a gate electrode 118 leading to the semiconductor device 100 as shown in FIG. 1A.

In the semiconductor device 100, a low on-state resistance is provided by the high electron mobility structure and the application of the compensation principle in the drift zone, wherein a high voltage blocking capability is provided by the drift zone 120 in the semiconductor body 102. Accordingly, a semiconductor device having an optimized on-state resistance and breakdown voltage is provided.

Thus, breakdown voltages above 1 kV or even above 3 kV are possible having at the same time an extremely low on-state resistance of the semiconductor device 100.

Terms such as “first,” “second,” and the like, are used to describe various structures, elements, regions, sections, etc. and are not intended to be limiting. Like terms refer to like elements throughout the description.

The terms “having,” “containing,” “including,” “comprising” and the like are open and the terms indicate the presence of stated elements or features, but not preclude additional elements or features. The articles “a,” “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor body of a first semiconductor material, wherein at least a part of the semiconductor body constitutes a drift zone of a first conductivity type; and
a channel layer structure comprising a semiconductor heterojunction between first and second semiconductor layers electrically coupled to the drift zone, the first and second semiconductor layers including semiconductor materials that are different to the first semiconductor material.

2. The semiconductor device of claim 1, further comprising a drift contact zone of the first conductivity type electrically coupled to the channel layer structure and the semiconductor body.

3. The semiconductor device of claim 1, wherein the semiconductor body has a first surface and a second surface opposite to the first surface, the channel layer structure is formed on the first surface, and a drain electrode is formed at the second surface of the semiconductor body being electrically coupled to the drift zone.

4. The semiconductor device of claim 1, wherein the first semiconductor material includes SiC.

5. The semiconductor device of claim 1, wherein the first and second semiconductor layers include GaN, AlGaN, Si, or Ge.

6. The semiconductor device of claim 1, further comprising a source contact zone of the first conductivity type at the first surface and a junction isolation zone of a second conductivity type in the semiconductor body for electrically insulating the source contact zone and the drift zone.

7. The semiconductor device of claim 1, wherein the channel layer structure comprises a buffer layer between the semiconductor heterojunction and the semiconductor body.

8. The semiconductor device of claim 1, further comprising a charge compensation structure in the semiconductor body.

9. A semiconductor device, comprising:
a semiconductor body of SiC, wherein at least a part of the semiconductor body of SiC constitutes a drift zone;
a channel layer structure comprising a high electron mobility transistor structure that is electrically connected to the drift zone; and
a charge compensation structure in the semiconductor body of SiC.

10. The semiconductor device of claim 9, wherein the channel layer structure comprises a semiconductor heterojunction or a layer structure including at least one of graphene and molybdenum disulfide.

11. The semiconductor device of claim 9, wherein the charge compensation structure comprises at least one trench extending into the semiconductor body.

12. The semiconductor device of claim 11, wherein a width of the at least one trench is smaller than 1 μm.

13. The semiconductor device of claim 11, wherein the at least one trench is at least partly filled with doped or undoped SiC.

14. The semiconductor device of claim 11, wherein the at least one trench is at least partly filled with diamond, boron nitride or phase change materials.

15. The semiconductor device of claim 11, wherein a ratio of widths of the drift zone and the at least one trench is higher than 10.

16. The semiconductor device of claim 9, further comprising an edge termination structure having trenches with decreasing depth with increasing distance to a transistor cell area.

17. A method for manufacturing a semiconductor device, comprising:
etching at least one trench in a semiconductor body of SiC;
doping a part of the semiconductor body of SiC via sidewalls of the at least one trench; and
forming a high electron mobility transistor structure in a channel layer structure above the semiconductor body of SiC.

18. The method of claim 17, further comprising:
forming a drain electrode at a surface of the semiconductor body of SiC opposite to the side of the channel layer structure, and
forming a source electrode electrically coupled to the high electron mobility transistor structure.

19. The method of claim 17, further comprising doping the part of the semiconductor body of SiC via sidewalls of the at least one trench by plasma doping.

20. The method of claim 17, further comprising doping the part of the semiconductor body of SiC via sidewalls of the at least one trench by a tilted ion implantation process.
